(19) United States
(12) Patent Application Publication
(10) Pub. No.: US 2026/0082798 A1
(43) Pub. Date: Mar. 19, 2026

(54) LIGHT LEAKAGE SUPPRESSION LAYER AND DISPLAY PANEL

(71) Applicant: AUO Corporation, Hsinchu City (TW)

(72) Inventors: Pin-Wei Ho, Hsinchu City (TW); YuTang Tsai, Hsinchu City (TW); Kun-Cheng Tien, Hsinchu City (TW); Shih-Hsiung Lin, Hsinchu City (TW)

(73) Assignee: AUO Corporation, Hsinchu City (TW)

(21) Appl. No.: 18/957,895

(22) Filed: Nov. 25, 2024

(30) Foreign Application Priority Data
Sep. 16, 2024 (TW) 113135108

(51) Int. Cl. H10K 59/80; H01L 25/075; H10K 77/10

(52) U.S. Cl. CPC H10K 59/8792; H10K 77/10; H10W 90/00

(57) ABSTRACT

A light leakage suppression layer includes multiple columnar structures separated from each other. In a top view of the light leakage suppression layer, the columnar structures comply with the following arrangement rules: each of the columnar structures and all other of the columnar structures having a fixed spacing A therebetween are connected by multiple virtual lines to form multiple hypothetical polygons, in which the virtual lines are of equal length, the columnar structures are located at corners and/or sides of the hypothetical polygons, and the hypothetical polygons include multiple different shapes.

### CROSS-REFERENCE TO RELATED APPLICATION

This application claims the priority benefit of Taiwan application serial no. 113135108, filed on Sep. 16, 2024. The entirety of the above-mentioned patent application is hereby incorporated by reference herein and made a part of this specification.

### BACKGROUND

### Technical Field

This disclosure relates to a light leakage suppression layer and a display panel.

### Description of Related Art

A transparent display panel is a light-transmitting display device that allows the user to see both the image information displayed and the background information behind the panel. These devices are used in a wide range of applications, such as vending machine windows, automobile windows, home windows, and storefront windows.

When the display panel displays an image, the light from the internal light source may be reflected inside the display panel, resulting in light leakage from the back of the display panel. Especially in the case of a large viewing angle, the image displayed by the display panel may be reflected at the interface between the display panel and the air, and such reflected light may leak out from the back of the display panel, which in turn affects the visual effect at the back.

### SUMMARY

The disclosure provides a light leakage suppression layer and a display panel that can improve a problem of uneven light leakage on a back side of the display panel.

At least one embodiment of the disclosure provides a light leakage suppression layer. The light leakage suppression layer includes multiple columnar structures separated from each other. In a top view of the light leakage suppression layer, the columnar structures comply with the following arrangement rules: each of the columnar structures and all other of the columnar structures having a fixed spacing A therebetween are connected by multiple virtual lines to form multiple hypothetical polygons, in which the virtual lines are of equal length, the columnar structures are located at corners and/or sides of the hypothetical polygons, and the hypothetical polygons include multiple different shapes.

At least one embodiment of the disclosure provides a display panel. The display panel includes multiple light-emitting elements and the light leakage suppression layer.

Based on the above, by adjusting arrangement of the columnar structures, the problem of uneven light leakage on the back side at different azimuth angles may be improved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a schematic cross-sectional diagram of a display panel according to an embodiment of the disclosure.

FIG. 2 is a schematic top diagram of a light leakage suppression layer according to an embodiment of the disclosure.

FIG. 3 is a schematic top view of a light leakage suppression layer according to an embodiment of the disclosure.

FIG. 4 is a schematic top diagram of a light leakage suppression layer according to an embodiment of the disclosure.

FIG. 5 is a schematic top diagram of a light leakage suppression layer according to an embodiment of the disclosure.

FIG. 6 is a schematic top diagram of a light leakage suppression layer according to an embodiment of the disclosure.

FIG. 7 is a schematic top diagram of a light leakage suppression layer according to an embodiment of the disclosure.

FIG. 8A is a three-dimensional schematic diagram of the light leakage suppression layer of FIG. 7.

FIG. 8B is a backside light leakage intensity distribution diagram of a display panel including the light leakage suppression layer of FIG. 7 at each tilt angle θ and each azimuth angle φ.

FIG. 9 is a backside light leakage intensity distribution diagram of a display panel including the light leakage suppression layer of FIG. 2 at each tilt angle θ and each azimuth angle φ.

FIG. 10 is a backside light leakage intensity distribution diagram of a display panel including the light leakage suppression layer of FIG. 3 at each tilt angle θ and each azimuth angle φ.

FIG. 11 is a backside light leakage intensity distribution diagram of a display panel including the light leakage suppression layer of FIG. 4 at each tilt angle θ and each azimuth angle φ.

FIG. 12 is a backside light leakage intensity distribution diagram of a display panel including the light leakage suppression layer of FIG. 5 at each tilt angle θ and each azimuth angle φ.

FIG. 13 is a backside light leakage intensity distribution diagram of a display panel including the light leakage suppression layer of FIG. 6 at each tilt angle θ and each azimuth angle φ.

FIG. 14A shows relative light leakage amount of the display panel of some embodiments of the disclosure at each tilt angle θ in direction x.

FIG. 14B shows relative light leakage amount of the display panel of some embodiments of the disclosure at each tilt angle θ in direction y.

FIG. 15A shows relative light leakage amount of the display panel of some embodiments of the disclosure at each tilt angle θ in direction x.

FIG. 15B shows relative light leakage amount of the display panel of some embodiments of the disclosure at each tilt angle θ in direction y.

### DESCRIPTION OF THE EMBODIMENTS

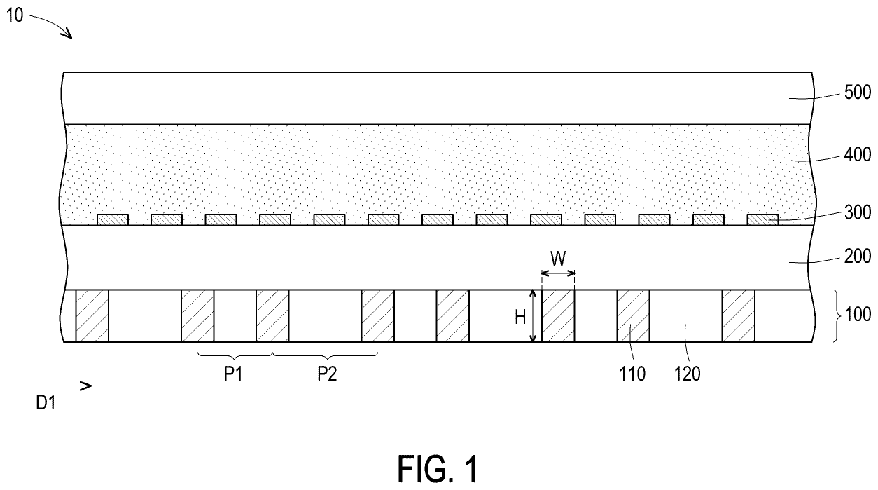

FIG. 1 is a schematic cross-sectional diagram of a display panel 10 according to an embodiment of the disclosure. Referring to FIG. 1, the display panel 10 includes a light leakage suppression layer 100, a first transparent substrate 200, multiple light-emitting elements 300, an optical adhesive layer 400, and a second transparent substrate 500.

The first transparent substrate 200 and the second transparent substrate 500 are, for example, rigid substrates, and their materials can be glass, quartz, organic polymers, or other applicable materials. However, the disclosure is not limited thereto. In other embodiments, the first transparent substrate 200 and the second transparent substrate 500 may also be flexible substrates or stretchable substrates. For example, materials for flexible substrates and stretchable substrates include polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (PU), or other suitable materials.

In some embodiments, the refractive index of the first transparent substrate 200 and the second transparent substrate 500 is about 1.5. In some embodiments, the first transparent substrate 200 has a thickness of approximately 400 microns to 1100 microns. In some embodiments, the second transparent substrate 500 may be omitted.

In some embodiments, a circuit structure (not shown) is disposed on the first transparent substrate 200 and includes, for example, multiple conductive layers and multiple insulating layers. In some embodiments, the circuit structure also includes multiple active elements and/or multiple passive elements, and the active elements may be thin film transistors.

The light-emitting element 300 is disposed on the first transparent substrate 200 and is electrically connected to the circuit structure on the first transparent substrate 200. In some embodiments, the light-emitting element 300 includes, for example, a micro light-emitting diode, a mini light-emitting diode, an organic light-emitting diode, or other suitable light-emitting element.

The optical adhesive layer 400 is located on the light-emitting element 300 and covers the light-emitting element 300. The light-emitting element 300 and the optical adhesive layer 400 are located between the first transparent substrate 200 and the second transparent substrate 500. The optical adhesive layer 400 is, for example, optically clear adhesive (OCA), optical clear resin (OCR), or other similar materials.

In some embodiments, the optical glue layer 400 has a refractive index of about 1.5 and a thickness of about 200 microns to 1000 microns.

The light leakage suppression layer 100 is located on the side of the first transparent substrate 200 opposite to the light-emitting element 300. In other words, the first transparent substrate 200 is located between the light-emitting element 300 and the light leakage suppression layer 100.

The light leakage suppression layer 100 includes discrete columnar structures 110. In other words, the columnar structures 110 are separated from each other. In some embodiments, the columnar structure 110 has a height H of 300 microns to 700 microns, and a width W of the columnar structure 110 ranges from 75 microns to 125 microns. In some embodiments, the columnar structure 110 includes a light-absorbing material for absorbing visible light, such as black resin, black metal, black oxide, or other suitable materials. In some embodiments, the shape of the columnar structure 110 includes a straight or funnel column of cylindrical or elliptical columns.

In some embodiments, transparent layers 120 are optionally included around the columnar structure 110. The transparent layers 120 are located between the columnar structures 110 and fill gaps between the columnar structures 110. In some embodiments, the transparent layers 120 surround the columnar structures 110 and do not cover top and bottom surfaces of the columnar structures 110, but the disclosure is not limited thereto. In other embodiments, the transparent layers 120 cover the top and/or bottom surfaces of the columnar structures 110. In some embodiments, the material of the transparent layers 120 includes glass, oxide, organic materials, or other suitable transparent materials.

In some embodiments, the arrangement of the columnar structures 110 is adjusted to reduce the regularity of the columnar structures 110, thereby improving the problem of uneven distribution of backside light leakage at different azimuth angles. For example, in a first direction D1, the columnar structures 110 have more than two spacings (such as a spacing P1 and a spacing P2), thereby reducing the regularity of the columnar structures 110.

In this embodiment, the display panel 10 is a transparent display panel, and a user located behind the display panel 10 are able to view the environment on the front side through the display panel 10. In this embodiment, the light emitted by the light-emitting element 300 in the display panel 10 is reflected within the display panel 10 and transmitted to the light leakage suppression layer 100. The reflected light passes through the light leakage suppression layer 100 from the gap of the columnar structure 110 and exits from the back side of the display panel 10, causing the problem of back side light leakage. In the embodiment of the disclosure, the uniformity of backside light leakage is improved by adjusting the arrangement of the columnar structures 110 to avoid obvious backside light leakage at a specific azimuth angle.

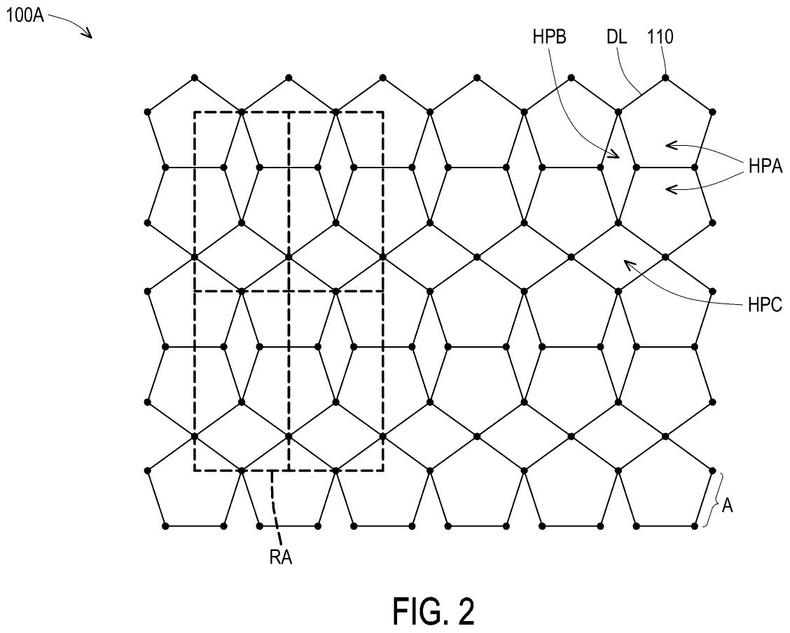

Various embodiments of the light leakage suppression layer are described below through FIG. 2 to FIG. 7. In FIG. 2 to FIG. 7, each of the columnar structures 110 and all other columnar structures having a fixed spacing A therebetween are connected by multiple virtual lines DL to form multiple hypothetical polygons HPA to HPQ having multiple different shapes. The columnar structures 110 are located at the corners and/or sides of the hypothetical polygons, so that the length of each side of each hypothetical polygon is a positive integer multiple of fixed spacing A. In some embodiments, the fixed spacing A ranges from 150 microns to 7000 microns. In a preferred embodiment, the hypothetical polygon in the light leakage suppression layer includes more than three different shapes, thereby improving the uniformity of backside light leakage. In a preferred embodiment, at least two shapes of the hypothetical polygon in the light leakage suppression layer are shapes with the length of each side being equal, thereby further improving the uniformity of backside light leakage.

In this article, the hypothetical polygons and the virtual lines DL are only used to illustrate the arrangement rules of the columnar structures 110, and are not actual components. In addition, each hypothetical polygon described herein has no other hypothetical polygons within its boundaries, and the hypothetical polygons are distributed in a planar and dense manner in the light leakage suppression layer. The sum of multiple angles corresponding to multiple hypothetical polygons that are close to each other around a columnar structure 110 is 360 degrees.

Referring to FIG. 2, in the top view of a light leakage suppression layer 100A, the columnar structures 110 comply with the following arrangement rules: each of the columnar structures 110 and all other columnar structures having a fixed spacing A therebetween are connected by multiple virtual lines DL to form multiple hypothetical polygons HPA, HPB, and HPC. The columnar structures 110 are located at the corners of the hypothetical polygon HPA, HPB, and HPC, so that the length of each side of the hypothetical polygon HPA, HPB, and HPC is equal (i.e., the length of each side is a fixed spacing A).

In the embodiment of FIG. 2, the hypothetical polygons HPA, HPB, and HPC include multiple different shapes. For example, the hypothetical polygons HPA, HPB, and HPC include three different shapes, in which the hypothetical polygon HPA is a pentagon, the hypothetical polygon HPB is a first prismatic shape, and the hypothetical polygon HPC is a second prismatic shape. The area of each first prismatic shape is different from the area of each second prismatic shape.

In the embodiment of FIG. 2, the hypothetical polygons HPA, HPB, and HPC are arranged into an array containing multiple repeating units RA. Herein, the repeating unit RA may also be referred to as the smallest repeating unit. Each repeating unit RA contains more than one columnar structure 110, and the columnar structures 110 in each repeating unit RA are arranged in the same manner. In the embodiment of FIG. 2, the shape of the repeating unit RA is rectangular.

In the embodiment of FIG. 2, after rotating the array of the columnar structures 110 by 180 degrees with the normal direction of the light leakage suppression layer 100A (i.e., the direction perpendicular to the plane of the paper in FIG. 2) as the rotation axis, a substantially identical array of the columnar structures 110 is obtained.

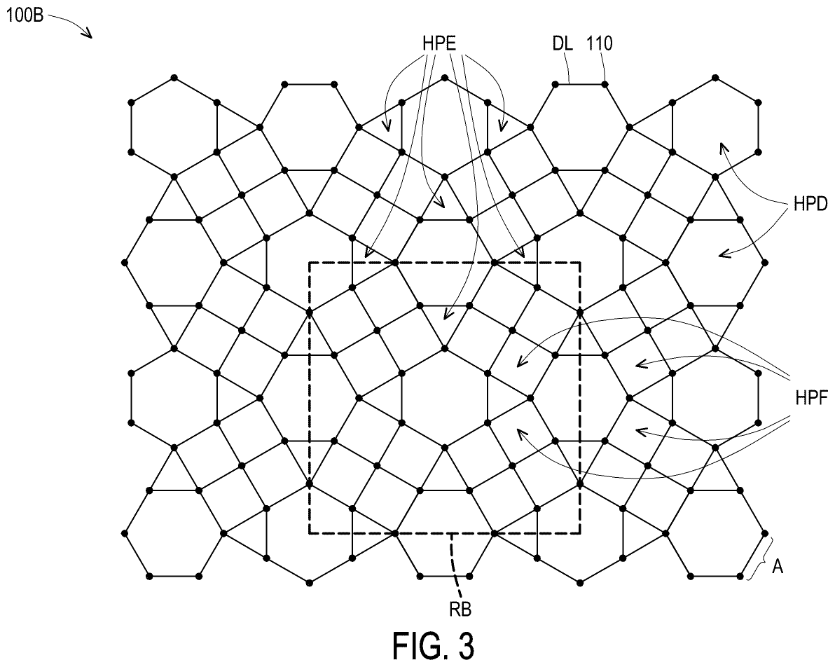

Referring to FIG. 3, in the top view of a light leakage suppression layer 100B, the columnar structures 110 comply with the following arrangement rules: each of the columnar structures 110 and all other columnar structures having a fixed spacing A therebetween are connected by multiple virtual lines DL to form multiple hypothetical polygons HPD, HPE, and HPF. The columnar structures 110 are located at the corners of the hypothetical polygon HPD, HPE, and HPF, so that the length of each side of the hypothetical polygon HPD, HPE, and HPF is equal (i.e., the length of each side is a fixed spacing A).

In the embodiment of FIG. 3, the hypothetical polygons HPD, HPE, and HPF include multiple different shapes. For example, the hypothetical polygon HPD, HPE, and HPF includes three different shapes, in which the hypothetical polygon HPD is a hexagon (e.g., a regular hexagon), the hypothetical polygon HPE is a triangle (e.g., an equilateral triangle), and the hypothetical polygon HPF is a square.

In the embodiment of FIG. 3, the hypothetical polygons HPD, HPE, and HPF are arranged into an array containing multiple repeating units RB. Herein, the repeating unit RB may also be referred to as the smallest repeating unit. Each repeating unit RB contains more than one columnar structure 110, and the columnar structures 110 in each repeating unit RB are arranged in the same manner. In the embodiment of FIG. 3, the shape of the repeating unit RB is a square.

In the embodiment of FIG. 3, after rotating the array of the columnar structures 110 by 90 degrees with the normal direction of the light leakage suppression layer 100B (i.e., the direction perpendicular to the plane of the paper in FIG. 3) as the rotation axis, a substantially identical array of the columnar structures 110 is obtained.

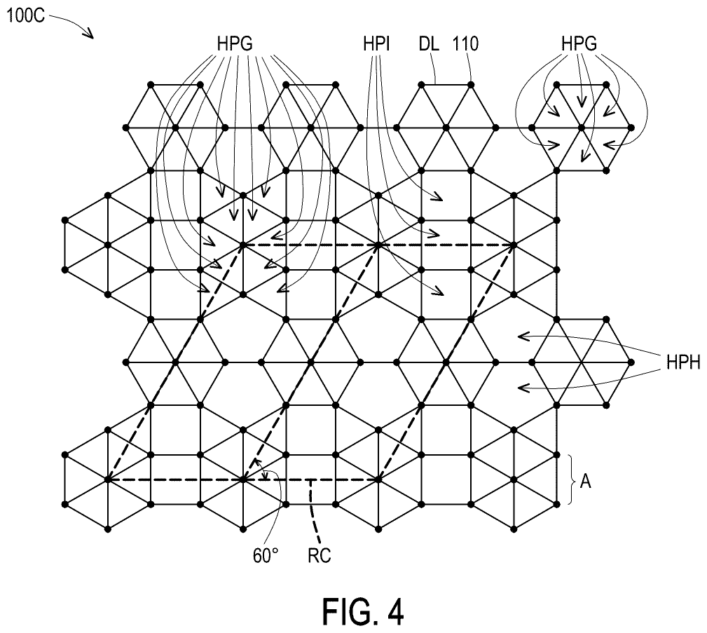

Referring to FIG. 4, in the top view of a light leakage suppression layer 100C, the columnar structures 110 comply with the following arrangement rules: each of the columnar structures 110 and all other columnar structures having a fixed spacing A therebetween are connected by multiple virtual lines DL to form multiple hypothetical polygons HPG, HPH, and HPI. The columnar structures 110 are located at the corners of the hypothetical polygon HPG, HPH, and HPI, so that the length of each side of the hypothetical polygon HPG, HPH, and HPI is equal (i.e., the length of each side is a fixed spacing A).

In the embodiment of FIG. 4, the hypothetical polygons HPG, HPH, HPI include multiple different shapes. For example, the hypothetical polygon HPG, HPH, and HPI includes three different shapes, in which the hypothetical polygon HPG is a triangle (e.g., an equilateral triangle), the hypothetical polygon HPH is a pentagon, and the hypothetical polygon HPI is a square.

In the embodiment of FIG. 4, the hypothetical polygons HPG, HPH, and HPI are arranged into an array containing multiple repeating units RC. Herein, the repeating unit RC may also be referred to as the smallest repeating unit. Each repeating unit RC contains more than one columnar structure 110, and the columnar structures 110 in each repeating unit RC are arranged in the same manner. In the embodiment of FIG. 4, the shape of the repeating unit RC is a parallelogram containing an acute angle of 60 degrees.

In the embodiment of FIG. 4, after rotating the array of the columnar structures 110 by 90 degrees with the normal direction of the light leakage suppression layer 100C (i.e., the direction perpendicular to the plane of the paper in FIG. 4) as the rotation axis, a substantially identical array of the columnar structures 110 is obtained.

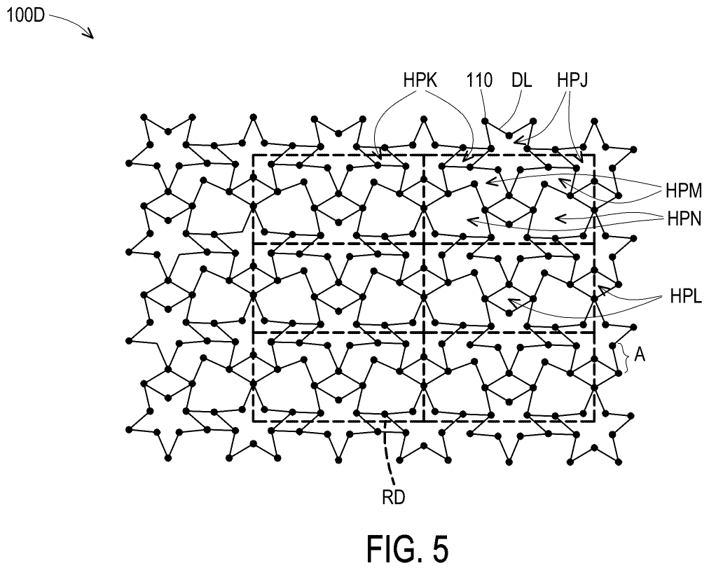

Referring to FIG. 5, in the top view of a light leakage suppression layer 100D, the columnar structures 110 comply with the following arrangement rules: each of the columnar structures 110 and all other columnar structures having a fixed spacing A therebetween are connected by multiple virtual lines DL to form multiple hypothetical polygons HPJ, HPK, HPL, HPM, and HPN. The columnar structures 110 are located at the corners of the hypothetical polygon HPJ, HPK, HPL, HPM, and HPN.

In the embodiment of FIG. 5, the hypothetical polygons HPJ, HPK, HPL, HPM, and HPN include multiple different shapes. For example, the hypothetical polygon HPJ, HPK, HPL, HPM, and HPN include five different shapes, in which the hypothetical polygon HPJ is a pentagram, the hypothetical polygon HPK is a first quadrilateral, the hypothetical polygon HPL is a second quadrilateral, the hypothetical polygon HPM is a first heptagon, and the hypothetical polygon HPN is a second heptagon. The area of each first quadrilateral is different from the area of each second quadrilateral. The area of each first heptagon is different from the area of each second heptagon.

In the embodiment of FIG. 5, the hypothetical polygons HPJ, HPK, HPL, HPM, and HPN are arranged into an array containing multiple repeating units RD. Herein, the repeating unit RD may also be referred to as the smallest repeating unit. Each repeating unit RD contains more than one columnar structure 110, and the columnar structures 110 in each repeating unit RD are arranged in the same manner. In the embodiment of FIG. 5, the shape of the repeating unit RD is rectangular.

In the embodiment of FIG. 5, after rotating the array of the columnar structures 110 by 180 degrees with the normal direction of the light leakage suppression layer 100D (i.e., the direction perpendicular to the plane of the paper in FIG. 5) as the rotation axis, a substantially identical array of the columnar structures 110 is obtained.

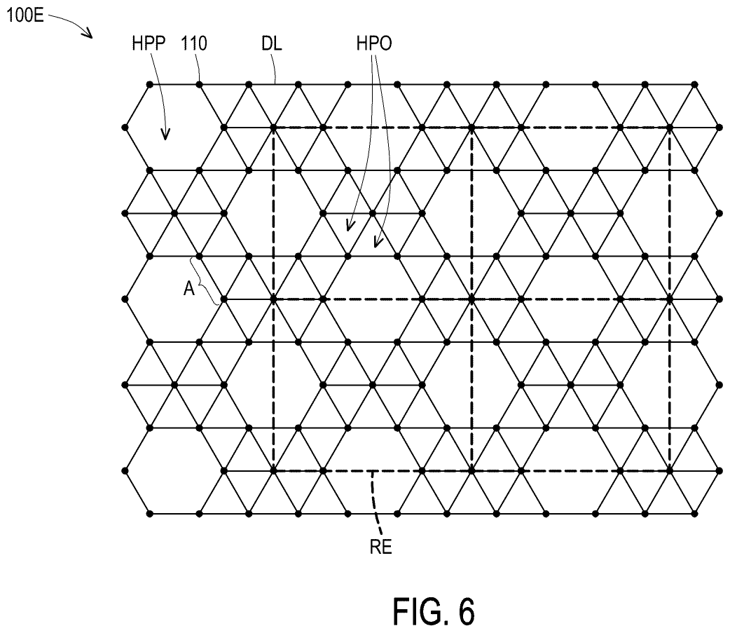

Referring to FIG. 6, in the top view of a light leakage suppression layer 100E, the columnar structures 110 comply with the following arrangement rules: each of the columnar structures 110 and all other columnar structures having a fixed spacing A therebetween are connected by multiple virtual lines DL to form multiple hypothetical polygons HPO and HPP. The columnar structures 110 are located at the corners of the hypothetical polygon HPO and HPP, so that the length of each side of the hypothetical polygon HPO and HPP is equal (i.e., the length of each side is a fixed spacing A).

In the embodiment of FIG. 6, the hypothetical polygon HPO and HPP includes multiple different shapes. For example, the hypothetical polygon HPO and HPP includes two different shapes, in which the hypothetical polygon HPP is hexagonal (e.g., regular hexagon), and the hypothetical polygon HPO is triangular (e.g., regular triangle).

In the embodiment of FIG. 6, the hypothetical polygons HPO and HPP are arranged into an array containing multiple repeating units RE. Herein, the repeating unit RE may also be referred to as the smallest repeating unit. Each repeating unit RE contains more than one columnar structure 110, and the columnar structures 110 in each repeating unit RE are arranged in the same manner. In the embodiment of FIG. 6, the shape of the repeating unit RE is a bounding rectangle.

In the embodiment of FIG. 6, after rotating the array of the columnar structures 110 by 180 degrees with the normal direction of the light leakage suppression layer 100E (i.e., the direction perpendicular to the plane of the paper in FIG. 6) as the rotation axis, a substantially identical array of the columnar structures 110 is obtained.

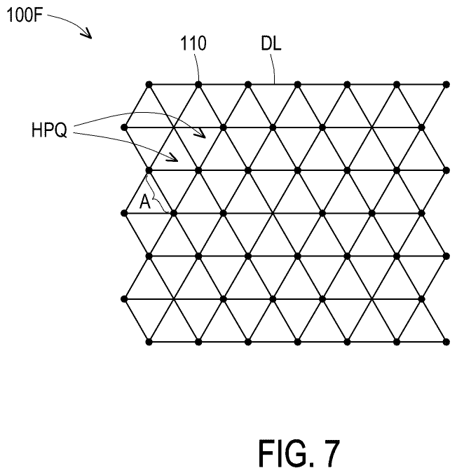

Referring to FIG. 7, in the top view of a light leakage suppression layer 100F, the columnar structures 110 comply with the following arrangement rules: each of the columnar structures 110 and all other columnar structures having a fixed spacing A therebetween are connected by multiple virtual lines DL to form multiple hypothetical polygons HPQ. The columnar structures 110 are located at the corners of the hypothetical polygon HPQ, so that the length of each side of the hypothetical polygon HPQ is equal (i.e., the length of each side is a fixed spacing A.

In the embodiment of FIG. 7, the hypothetical polygon HPQ includes only one shape. For example, the hypothetical polygon HPQ is an equilateral triangle.

The columnar structures 110 in the light leakage suppression layer 100F of FIG. 7 has a more regular arrangement than the columnar structures 110 in the light leakage suppression layer 100A to 100E of FIG. 2 to FIG. 6, and in the light leakage suppression layer 100F of FIG. 7, only a single shape of the hypothetical polygon HPQ can be defined. As a result, the light leakage suppression layer 100F in FIG. 7 is prone to uneven light leakage on the back side.

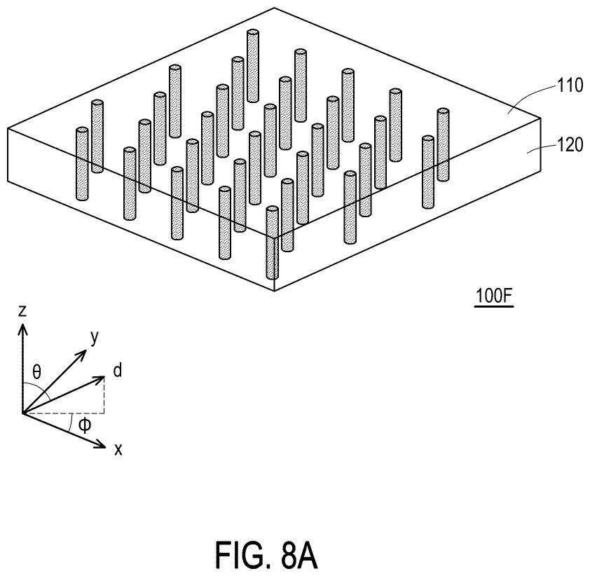

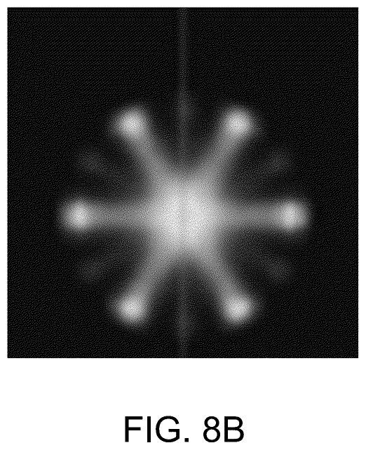

FIG. 8A is a three-dimensional schematic diagram of the light leakage suppression layer 100F of FIG. 7. FIG. 8B is a backside light leakage intensity distribution diagram of a display panel including the light leakage suppression layer 100F of FIG. 7 at each tilt angle θ and each azimuth angle q. The structure of the display panel can be referred to FIG. 1, and the difference is only that the arrangement of the columnar structures 110 in the light leakage suppression layer is adjusted to the arrangement shown in FIG. 7.

Referring to FIG. 8A and FIG. 8B, the tilt angle θ refers to the angle between a vertical direction z and a measurement direction d (i.e., the direction in which the light leakage is measured), while the azimuth angle φ refers to the angle between the vertical projection of the measurement direction d on the xy-plane (i.e., the plane in which the directions x and y are located) and the direction x.

It can be found from FIG. 8B that there is relatively obvious backside light leakage at positions where the azimuth angle q is 0 degrees, 60 degrees, 120 degrees, 180 degrees, 240 degrees, and 300 degrees, which is caused by the excessively regular arrangement of the columnar structures 110.

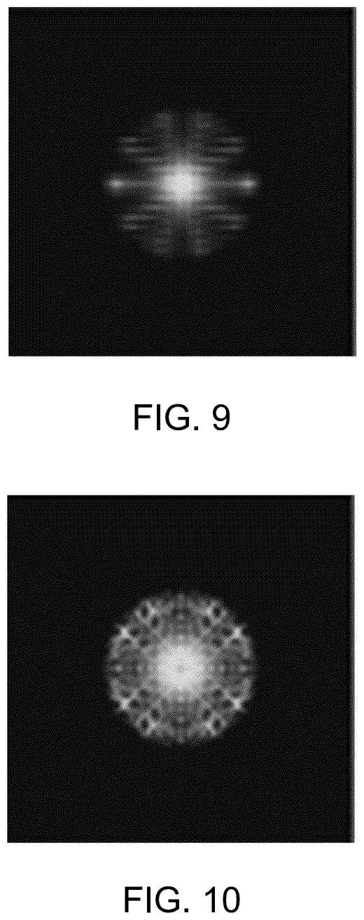

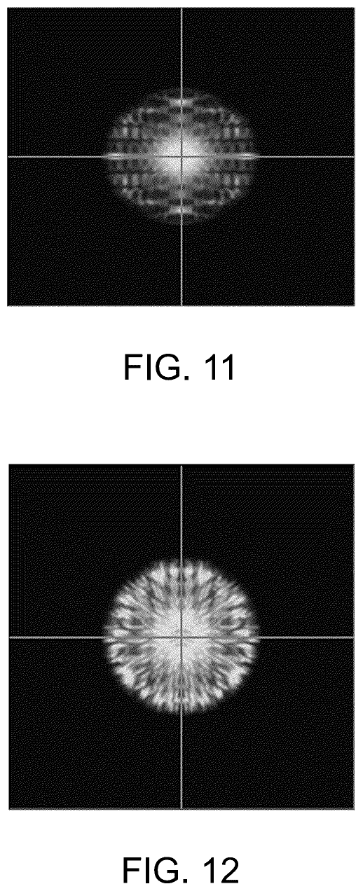

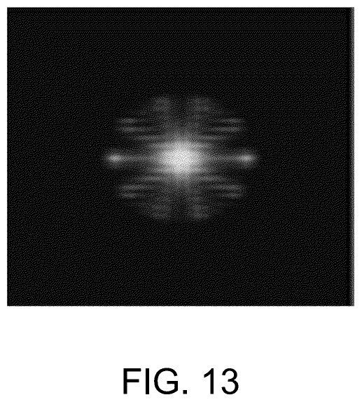

FIG. 9 to FIG. 13 are respectively backside light leakage intensity distribution diagrams of the display panel including the light leakage suppression layers of FIG. 2 to FIG. 6 at each tilt angle θ and each azimuth angle q. The structure of the display panel can be referred to FIG. 1, and the difference is only that the arrangement of the columnar structures 110 in the light leakage suppression layer is adjusted to the arrangement shown in FIG. 2 to FIG. 6 respectively.

Comparing FIG. 8B and FIG. 9 to FIG. 13, it can be found that the distribution of backside light leakage becomes more uniform in FIG. 9 to FIG. 13, which is caused by reducing the regularity of the arrangement of the columnar structures 110. It can be seen that by adjusting the arrangement of the columnar structures 110, the problem of obvious light leakage at a specific azimuth angle θ may be avoided.

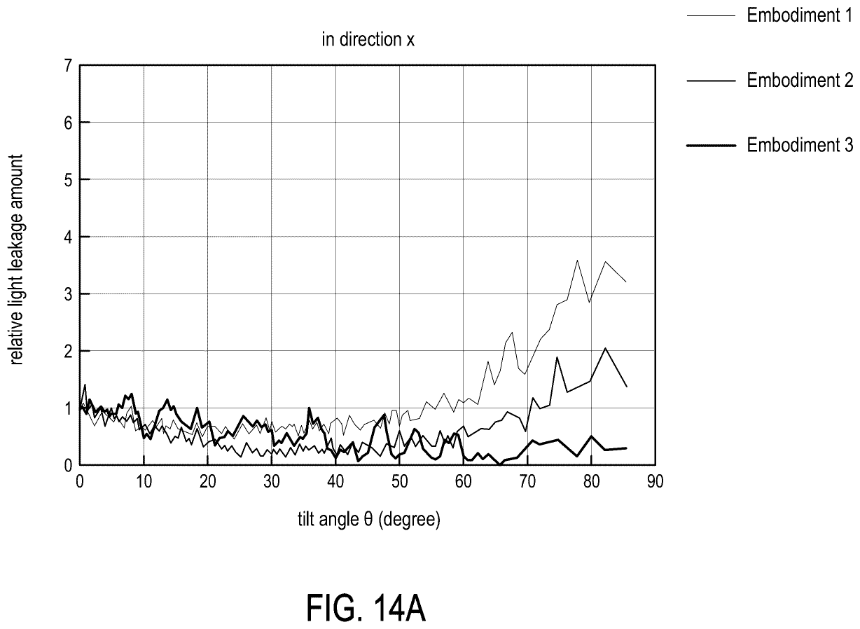

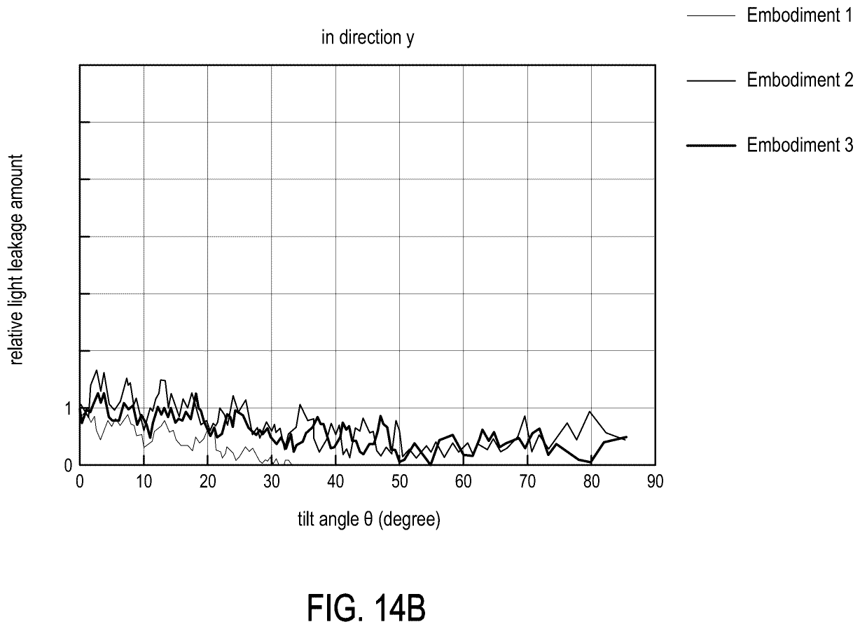

FIG. 14A shows relative light leakage amount of the display panel of some embodiments of the disclosure at each tilt angle θ in direction x. FIG. 14B shows relative light leakage amount of the display panel of some embodiments of the disclosure at each tilt angle θ in direction y. The relative light leakage amount refers to the ratio of the light leakage intensity measured at a certain tilt angle θ to the light leakage intensity measured at the tilt angle θ=0°.

In FIG. 14A and FIG. 14B, various parameters of the display panels of embodiment 1, embodiment 2, and embodiment 3 are as shown in Table 1.

TABLE 1

| | | | fixed | | relative peak | relative peak |
|---|---|---|---|---|---|---|
| | width of | height of | spacing A | aperture | light leakage in | light leakage in |
| | columnar | columnar | of columnar | ratio of | direction x and | direction y and |
| | structure | structure | structure | display panel | corresponding | corresponding |
| | (micron) | (micron) | (micron) | (%) | tilt angle θ | tilt angle θ |
| embodiment 1 | 75 | 700 | 200 | 87.3 | 3.60 | 1.00 |
| | | | | | (77.6°) | (0°) |
| embodiment 2 | 75 | 700 | 200 | 88.9 | 2.05 | 1.00 |
| | | | | | (81.9°) | (0°) |
| embodiment 3 | 75 | 700 | 200 | 89.6 | 1.00 | 1.00 |
| | | | | | (0°) | (0°) |

In FIG. 14A, FIG. 14B, and embodiment 1 of Table 1, the columnar structures are arranged in the manner shown in FIG. 7. In FIG. 14A, FIG. 14B, and embodiment 2 of Table 1, the columnar structures are arranged in the manner shown in FIG. 2. In FIG. 14A, FIG. 14B, and embodiment 3 of Table 1, the columnar structures are arranged in the manner shown in FIG. 3.

Comparing embodiment 1 to embodiment 3, it can be found that arranging the columnar structures in the manner of FIG. 2 and FIG. 3 can effectively reduce the relative light leakage peak in the direction x.

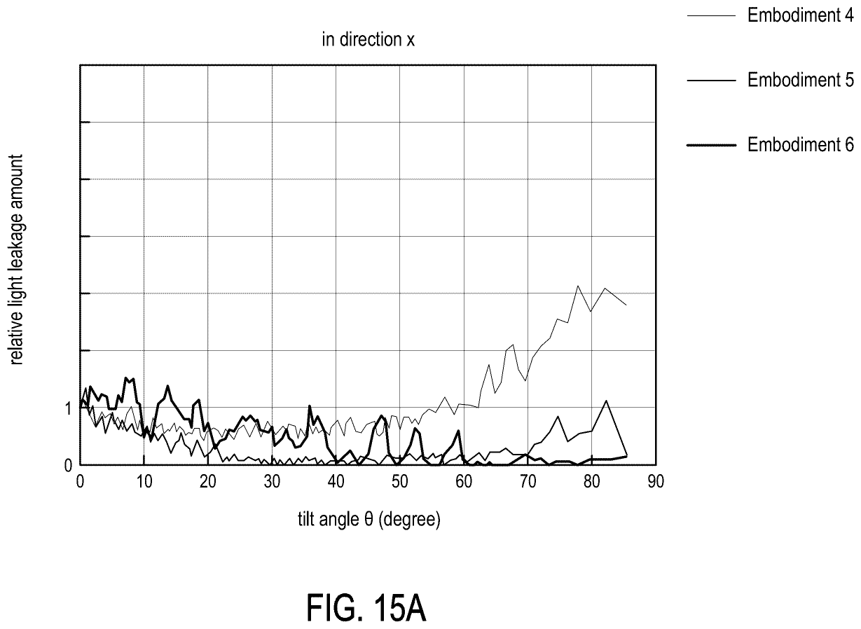

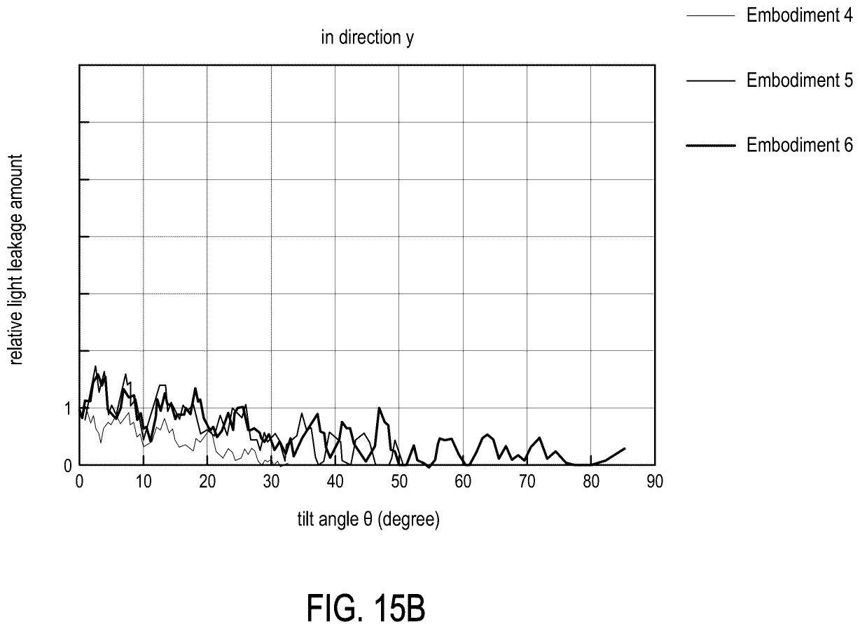

FIG. 15A shows relative light leakage amount of the display panel of some embodiments of the disclosure at each tilt angle θ in direction x. FIG. 15B shows relative light leakage amount of the display panel of some embodiments of the disclosure at each tilt angle θ in direction y.

In FIG. 15A and FIG. 15B, various parameters of the display panels of embodiment 4, embodiment 5, and embodiment 6 are shown in Table 2.

TABLE 2

| | | | fixed | | relative peak | relative peak |
|---|---|---|---|---|---|---|
| | width of | height of | spacing A | aperture | light leakage in | light leakage in |
| | columnar | columnar | of columnar | ratio of | direction x and | direction y and |
| | structure | structure | structure | display panel | corresponding | corresponding |
| | (micron) | (micron) | (micron) | (%) | tilt angle θ | tilt angle θ |
| embodiment 4 | 81 | 700 | 200 | 85 | 3.12 | 1.00 |
| | | | | | (77.6°) | (0°) |
| embodiment 5 | 87 | 700 | 200 | 85 | 1.00 | 1.00 |
| | | | | | (0°) | (0°) |
| embodiment 6 | 90 | 700 | 200 | 85 | 1.00 | 1.00 |
| | | | | | (0°) | (0°) |

In FIG. 15A, FIG. 15B, and embodiment 4 of Table 2, the columnar structures are arranged in the manner shown in FIG. 7. In FIG. 15A, FIG. 15B, and embodiment 5 of Table 2, the columnar structures are arranged in the manner shown in FIG. 2. In FIG. 15A, FIG. 15B, and embodiment 6 of Table 2, the columnar structures are arranged in the manner shown in FIG. 3.

Comparing embodiment 4 to embodiment 6, it can be found that arranging the columnar structures in the manner of FIG. 2 and FIG. 3 can effectively reduce the relative light leakage peak in the direction x.

To sum up, in the embodiment of the disclosure, in the top view of the light leakage suppression layer, each of the columnar structures and all other columnar structures having a fixed spacing A therebetween are connected by multiple virtual lines to form multiple hypothetical polygons. The hypothetical polygon includes multiple different shapes. By adjusting the arrangement of the columnar structures, the uniformity of backside light leakage may be improved. In a preferred embodiment, the hypothetical polygon includes more than three different shapes, and at least two of the shapes are shapes with the length of each side being equal, thereby further improving the problem of backside light leakage.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A light leakage suppression layer, comprising:
a plurality of columnar structures, the columnar structures being separated from each other, wherein in a top view of the light leakage suppression layer, the columnar structures comply with the following arrangement rules:
each of the columnar structures and all other of the columnar structures having a fixed spacing A therebetween are connected by a plurality of virtual lines to form a plurality of hypothetical polygons, wherein the virtual lines are of equal length, the columnar structures are located at corners and/or sides of the hypothetical polygons, and the hypothetical polygons comprise a plurality of different shapes.

2. The light leakage suppression layer according to claim 1, wherein all of the columnar structures are located at a plurality of corners of the hypothetical polygons, and a side length of each of the sides of each of the hypothetical polygons is equal.

3. The light leakage suppression layer according to claim 1, wherein the hypothetical polygons comprise more than three different shapes, and at least two of the shapes are shapes with side lengths of each of the sides being equal.

4. The light leakage suppression layer according to claim 1, wherein the hypothetical polygons comprise a plurality of pentagons, a plurality of first prismatic shapes, and a plurality of second prismatic shapes, wherein an area of each of the first prismatic shapes is different from an area of each of the second prismatic shapes.

5. The light leakage suppression layer according to claim 1, wherein the hypothetical polygons comprise a plurality of hexagons, a plurality of triangles, and a plurality of squares.

6. The light leakage suppression layer according to claim 1, wherein the hypothetical polygons comprise a plurality of pentagons, a plurality of triangles, and a plurality of squares.

7. The light leakage suppression layer according to claim 1, wherein the hypothetical polygons comprise a plurality of pentagrams, a plurality of first quadrilaterals, a plurality of second quadrilaterals, a plurality of first heptagons, and a plurality of second heptagons, wherein an area of each of the first quadrilaterals is different from an area of each of the second quadrilaterals, and an area of each of the first heptagons is different from an area of each of the second heptagons.

8. The light leakage suppression layer according to claim 1, wherein a sum of a plurality of angles corresponding to a plurality of hypothetical polygons that are close to each other among the hypothetical polygons is 360 degrees.

9. The light leakage suppression layer according to claim 1, comprising:
a transparent layer, located between the columnar structures.

10. The light leakage suppression layer according to claim 1, wherein a height of the each of the columnar structures is 300 microns to 700 microns, a width of the each of the columnar structures is 75 microns to 125 microns, and the columnar structures comprise light-absorbing materials for absorbing visible light.

11. The light leakage suppression layer according to claim 1, wherein the hypothetical polygons are arranged into an array comprising a plurality of repeating units.

12. The light leakage suppression layer according to claim 1, wherein the columnar structures comprise different spacings in a first direction.

13. A display panel, comprising:
a plurality of light-emitting elements; and
a light leakage suppression layer according to claim 1.

14. The display panel according to claim 13 further comprising:
a transparent substrate, wherein the transparent substrate is located between the light-emitting elements and the light leakage suppression layer.
